(19) United States
(12) Patent Application Publication
(10) Pub. No.: US 2017/0077046 A1
(43) Pub. Date: Mar. 16, 2017

(54) PHYSICAL UNCLONABLE FUNCTIONS THROUGH LOCALLY ENHANCED DEFECTIVITY

(71) Applicant: THE REGENTS OF THE UNIVERSITY OF CALIFORNIA, Oakland, CA (US)

(72) Inventors: Puneet Gupta, Los Angeles, CA (US); Wei-Che Wang, Los Angeles, CA (US)

(21) Appl. No.: 15/263,184

(22) Filed: Sep. 12, 2016

Related U.S. Application Data
(60) Provisional application No. 62/217,510, filed on Sep. 11, 2015.

(51) Int. Cl. H01L 23/00; H01L 51/00; H01L 51/05; H03K 19/003; H01L 29/40; H01L 49/02; H03K 19/21; H01L 27/02; H01L 45/00

(52) U.S. Cl. CPC H01L 23/576; H01L 27/0207; H01L 51/0048; H01L 51/0512; H01L 45/085; H01L 29/408; H01L 28/40; H03K 19/21; H03K 19/00315

(57) ABSTRACT

A physical unclonable function (PUF) includes multiple logic gates and multiple random signal generation circuits connected to the logic gates, wherein, in at least a subset of the logic gates, each logic gate includes an input having a logic value that is specified by at least one of the random signal generation circuits. Each of the random signal generation circuits includes a random hard-defect feature, such as a random hard-defect shorted path.

### CROSS REFERENCE TO RELATED APPLICATION

This application claims the benefit of U.S. Provisional Application Ser. No. 62/217,510, filed on Sep. 11, 2015, the content of which is incorporated herein by reference in its entirety.

### TECHNICAL FIELD

This disclosure generally relates to physical unclonable functions and, more particularly, physical unclonable functions implemented through locally enhanced defectivity.

### BACKGROUND

A physical unclonable function (PUF) generally refers to a physical structure, such as a small piece of circuitry, having a behavior, or a challenge-response pair (CRP), that is distinctly specified and is hard to be predicted and replicated because of its intrinsic random physical nature. As a security primitive, a PUF can provide for low overhead hardware identification, tracing, and authentication in a global manufacturing chain.

Many silicon PUF implementations use parametric manufacturing variations as a source of randomness. The use of parametric variations makes stability of the PUF response a concern, because the PUF is susceptible to environmental fluctuations and wearout. Some complex techniques have been proposed to mitigate stability issues, often at a cost of a reduced number of challenges to the PUF, circuit complexity, or increased susceptibility to model building attacks.

It is against this background that a need arose to develop the embodiments described herein.

### SUMMARY

In some embodiments, a PUF includes multiple logic gates and multiple random signal generation circuits connected to the logic gates, wherein, in at least a subset of the logic gates, each logic gate includes an input having a logic value that is specified by at least one of the random signal generation circuits. In some embodiments, each of the random signal generation circuits includes a random hard-defect feature, such as a random hard-defect shorted path. In some embodiments, each random hard-defect feature has a fixed connectivity state that specifies one of multiple distinct logic values, such as a logic “1” or a logic “0”.

In additional embodiments, a random signal generation circuit includes a switch and an electrically parallel configuration of a capacitor and a random hard-defect feature. A first side of the switch is configured for connection to a power source. The capacitor and the random hard-defect feature are connected to a second side of the switch at a first node, and are configured for connection to a ground potential at a second node. When the switch is closed and then opened, a logic value at the first node is specified by the random hard-defect feature.

In further embodiments, a method of evaluating a PUF includes activating multiple switches to apply a voltage to respective sub-circuits connected to the switches, wherein each of the sub-circuits includes a respective random hard-defect feature. The method also includes deriving logic values from outputs of the sub-circuits, wherein an output of each of the sub-circuits is set by a fixed connectivity state of the respective random hard-defect feature, and is derived as either a logic “1” or a logic “0”.

Other aspects and embodiments of this disclosure are also contemplated. The foregoing summary and the following detailed description are not meant to restrict this disclosure to any particular embodiment but are merely meant to describe some embodiments of this disclosure.

### BRIEF DESCRIPTION OF THE DRAWINGS

For a better understanding of the nature and objects of some embodiments of this disclosure, reference should be made to the following detailed description taken in conjunction with the accompanying drawings.

FIG. 1 is a chart of frequencies of inter-distance of PUFs from a same (X,Y) location on different wafers.

FIG. 2 is an illustration of directed self-assembly of a block copolymer (BCP).

FIG. 3 is a schematic illustration of a random hard-defect shorted path implemented by a carbon nanotube transistor.

FIG. 4 is a schematic illustration of a random hard-defect shorted path implemented by a memristor.

FIG. 5A is a top-view illustration of physically adjacent vias, in which two of the vias are merged.

FIG. 5B is a cross-section view illustration of physically adjacent vias, in which two of the vias are merged.

FIG. 5C is a schematic illustration of a random hard-defect shorted path implemented by a merging of two vias.

FIG. 6A and FIG. 6B are schematic illustrations of two types of gate oxide breakdown. Soft breakdown occurs when traps start to overlap and form a conducting path from a gate to a substrate (FIG. 6A). Hard breakdown occurs the oxide is physically tunneled through (FIG. 6B).

FIG. 7A and FIG. 7B are schematic illustrations of a random hard-defect implemented by exploiting gate oxide breakdown in a transistor. If oxide breakdown does not occur, the device is a capacitor, and an output is “0” (FIG. 7A). If oxide breakdown occurs, the device becomes a set of resistors, and the output is “1” (FIG. 7B).

FIG. 8 is a schematic illustration of a random signal generation circuit.

FIG. 9 is a schematic illustration of another random signal generation circuit.

FIG. 10A is a circuit diagram of a logic circuit.

FIG. 10B is the circuit diagram of FIG. 10A, with random signal generation circuits included to apply inputs to logic gates of the logic circuit.

FIG. 11 is a schematic illustration of a Locally Enhanced Defectivity PUF (LEDPUF) with n challenges and m-bit response.

### DETAILED DESCRIPTION

An assumption of parametric PUFs is that local variation should be the sole (or at least primary) entropy source for these PUFs. However, from experiments on a large silicon data set, the portion of manufacturing variation arising from random local variation is relatively small (accounting for about 13% of total variation), which means that most variation arises from global or spatial variation. An attempt to use global or spatial variation as a source of randomness can render a PUF vulnerable to a class of process side channel attacks. For instance, two PUFs on the same (X,Y) location on different wafers can be highly correlated (due to large wafer-level systematics present in many modern fabrication processes). As a result, a few sacrificial wafers can aid in developing a relatively straightforward side channel attack. Reinterpreting silicon data on ring oscillator measurements in 65 nanometer (nm) technology across more than 300 wafers as PUFs, such a side channel attack capability was tested.

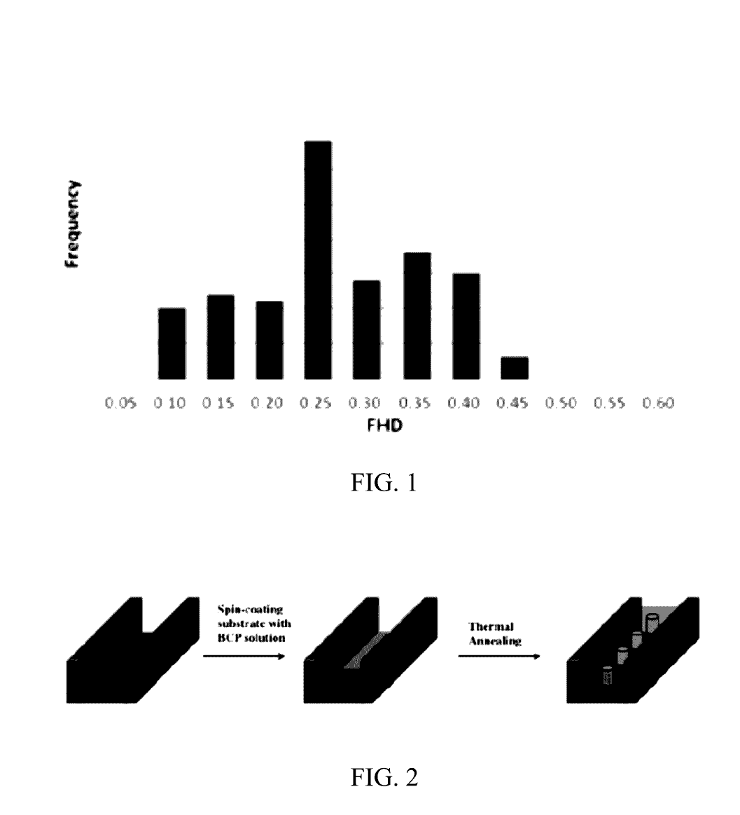

FIG. 1 shows a chart of frequencies of fractional hamming distance (FHD) inter-distance of PUFs from a same (X,Y) location on different wafers. By way of comparison, the inter-distance mean is about 0.5 across all PUFs on all tested wafers. Thus, FIG. 1 shows that an inter-distance mean for the same (X,Y) position on different wafers is much smaller than the inter-distance mean across all PUFs on all tested wafers. Accordingly, for silicon fabrication side channel attacks, an adversary with possession of a reference PUF, which is fabricated at the same (X,Y) location as a target PUF, would have a higher probability to predict a correct behavior than random guessing. The radial nature of systematic across-wafer variation means that just a few reference PUFs carefully selected may be sufficient to map a wafer, instead of keeping full sacrificial wafers.

Additionally, parametric PUFs are susceptible to environmental fluctuations and wearout, and measurement noise should also be accounted for carefully. For instance, metastability of an arbiter circuit for arbiter PUFs, and accumulated jitter in ring oscillator PUFs can be a concern.

The above discussion motivates the design of PUFs which do not rely on parametric manufacturing variations (and manifested as parametric performance variations such as delay, power, transistor drive strength, and so forth) as the entropy source. Compared to parametric PUFs, a functional PUF as described in the present disclosure has an advantage of stability.

Described in the present disclosure are Locally Enhanced Defectivity PUFs (LEDPUFs), where random uncontrollable perturbations in a manufacturing process result in hard defects. For instance, hard defects can be generated as random permanent connections. As a result, these LEDPUFs are stable by design, as they do not rely on parametric variation. Moreover, use of random defectivity as the source of entropy renders LEDPUFs more resistant to process side channel attacks or model building attacks. These defect-based LEDPUFs are functional in nature, in that a random change in logic function of an LEDPUF results from a defect. The logic function itself is the signature and can generate a variety of challenge-response pairs as desired. The Boolean nature of the response without parametric dependence means that LEDPUFs are substantially immune to measurement noise and wearout, and also offer greater reliability and reduced susceptibility to environmental fluctuations.

To realize an LEDPUF, custom PUF-specific fabrication processes, which locally enhance defects, can be used. Alternatively or additionally, layout approaches can be used to achieve high local defectivity by leveraging patterning technologies. A variety of techniques for practical realizations of LEDPUFs are described below.

In some embodiments, defects are enhanced on a via layer, such that random connectivity can result in random logic functions. In some embodiments, defects are enhanced within a plane, such as within a layer of a substrate. In some embodiments, defects are enhanced between planes. Further, different techniques can be used in combination to implement random logic functions within an LEDPUF, for increased resistance to attacks. Defects enhanced on a via layer are described in detail below by way of illustration; however, it should be understood that the techniques described can be extended to other implementations.

To avoid floating nets, potential locations of defects can be restricted, thereby setting a bound on a number of possible logic function realizations. Then, a choice of a logic fabric as well as a choice of candidate defect locations render model building attacks difficult. The choice of a logic fabric can also dictate a number of CRPs available (e.g., the random logic function) before an adversary can identify defect locations.

Several techniques are next described that can be used to generate random hard-defect shorted paths, such as random hard-defect vias. Other techniques are also within the scope of the present disclosure. Different ones of the techniques can also be used in combination to implement random logic functions with LEDPUFs.

Directed Self-Assembly

Directed self-assembly (DSA) patterning can be used to insert randomness to generate LEDPUFs. Self-assembly occurs when block copolymers (BCPs) composed of immiscible blocks phase-separate into organized structures. For instance, a diblock copolymer (with a particular composition) can self-assemble into structures of one type of block in a matrix of another type of block. Lithographically-printed templates (graphoepitaxy technique) or chemically-treated surfaces (chemoepitaxy technique) can be used to direct the self-assembly process. A graphoepitaxy process for contact or via holes is shown in FIG. 2, where a guiding template is lithographically printed first, then a surface is spin-coated with a BCP solution. Upon thermal annealing, a phase separation occurs, and with a particular BCP composition and surface treatment of a substrate, cylinders of one block are formed in a matrix of another block.

In case of a diblock copolymer made of two blocks, for instance A and B, at equilibrium, a microphase separation is established by an energy balance between the stretching energy for polymer chains and energy of interactions at an interface between A and B microdomains. In the DSA process, the size of a guiding template can affect the defect density. The assembled result is the minimum energy state, which can strong depends on the level of confinement achieved by the layout of the guiding template. Thermal equilibrium is achieved when the free energy is minimized. Free energy increases as the difference between the size of the guiding template and the natural pitch of the copolymer increases. Accordingly, in the case of larger-sized templates, it becomes energetically less expensive to induce a defect than to achieve a defect-free energy minimization. Additionally, a same size of a guiding template can lead to a different number of assembled structures, and this randomness in the number of assembled structures also increases with larger-sized guiding templates. Therefore, assembly results can be varied randomly by designing guiding templates (a) which are susceptible to lithographic variation; and (b) are likely to cause random assembly defects even if there are no lithographic errors.

The randomness in DSA can be used to fabricate LEDPUFs using randomly assembled shorted paths. For instance, to generate a DSA random hard defective connection, the size of a guiding template can be selected so that two adjacent vias are formed with a certain probability that they merge and are connected permanently. A resulting DSA hard defective connection is composed of the two vias along with their connection.

Carbon Nanotubes

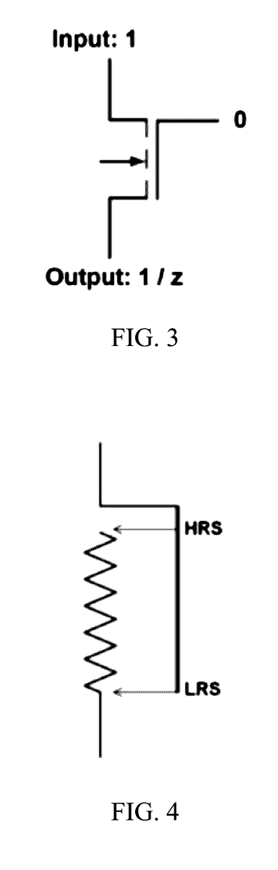

The manufacturing of carbon nanotubes (CNTs) is susceptible to process variations that are challenging to control. A major variation occurring in CNTs is with respect to chirality, which specifies the type of a CNT to be metallic or semiconducting. When a CNT transistor is on, both metallic and semiconducting CNTs form a conducting path between a source and a drain, similar to other complementary-metal-oxide-semiconductor (CMOS) transistors. However, when a metallic CNT transistor is turned off, it is still conducting, which leads to a shorted path between a source and a drain. In a typical transistor, this feature is generally undesirable. However, random chirality can be a source of randomness for hard-defect shorted paths according to some embodiments of the present disclosure. In an LEDPUF implemented with CNTs, a CNT field-effect transistor (CNTFET) can be used as a random hard-defect via. FIG. 3 shows an example of a hard-defect via implementation using a CNTFET. A gate is connected to a low voltage, and an input terminal is connected to a high voltage. If the CNT is metallic (forming a via), an output at an output terminal is high or a logic value of “1”; if the CNT is semiconducting, the via is not formed, and the output is at a high impedance state or a logic value of “0”.

Note that, alternatively or additionally to using the chirality of CNTs to form a via by way of a random shorted path between a source and a drain, the chirality can be used to form a random shorted path between a gate and the drain or the gate and the source. Further, a transistor implementation is provided as an example for purposes of explanation; however, it should be understood that random shorted paths can be formed in other semiconductor devices.

Memory Resistors (Memristors)

To write a logic “1” to a memristor cell, an input voltage pulse with a certain minimum magnitude and minimum width can be used to configure a length of a doped region to be longer than a threshold length. Similarly, to write a logic “0” to the memristor cell, a negative input voltage pulse is applied to configure the length of the doped region to be shorter than the threshold length. Due to process variations, a carefully calibrated “weak write” can write about half of memristor cells to “1”, and about another half to “0”. When a logic “1” is stored in a memristor cell, the cell is in a low resistance state (LRS); if a logic “0” is stored in a memristor cell, the cell is in a high resistance state (HRS) with about a 400 times larger resistance than a cell in a LRS.

Another feature of memristors useful for PUF implementation is that even if memristor cells are properly configured to either LRS or HRS, the resistances of the memristor cells typically follow a normal distribution, which can be further exploited for the implementation of a stable non-volatile PUF. Through digitizing and reprogramming mechanisms, about half of memristor cells in a memory array can be configured to a LRS, and about another half configured to a HRS, with randomly distributed locations. With this source of randomness and the large resistance gap between the LRS and the HRS, the LRS can be considered as an effective random hard-defect shorted path, so that the random LRS/HRS configuration can be used to construct an LEDPUF from an array of memristor cells.

FIG. 4 shows a memristor implementation of a hard-defect shorted path. If the memristor is in a LRS, a shorted path is effectively formed. If the memristor is in a HRS, a shorted path is not formed. If the device is connected to a fully charged capacitor, a difference in discharging time between a LRS memristor and a HRS memristor is significant if the capacitor is large enough. For instance, for an about 0.1 μf capacitor, a LRS memristor with about 0.5 megaohm (MΩ) resistance takes less than about 0.5 seconds to discharge the capacitor from about 1 Volt (V) to 0 V, while for a HRS memristor, the voltage is still above about 0.5 V after about 10 seconds.

Process Variation Enhancement

Intentionally enhancing a manufacturing process variation can be used to implement LEDPUFs. There are many sources of variations during semiconductor manufacturing, such as exposure intensity, variations in lenses, defocus, or optical proximity effects. Techniques, such as optical proximity correction (OPC), are used to suppress these manufacturing variations in a typical semiconductor fabrication flow. However, these variations can be exploited to implement LEDPUFs. For instance, a Litho-PUF technique extracts randomness from lithographic variations by placing polygons, such as interconnects or gates, near forbidden pitch zones, because small lithographic variations can lead to large variations in critical dimensions. An objective function can generate masks that enhance such fabrication variations in regions where PUF circuits are to be positioned. Further, in addition to inter-die uniqueness, inter-wafer uniqueness of PUFs can also be improved by performing manufacturing-aware physical design. Therefore, if structures in circuit layouts, such as at connections or polysilicon gates, are fabricated near process window boundaries, process variations can become difficult to control, and randomness can be exploited in the generation of random hard-defect shorted paths.

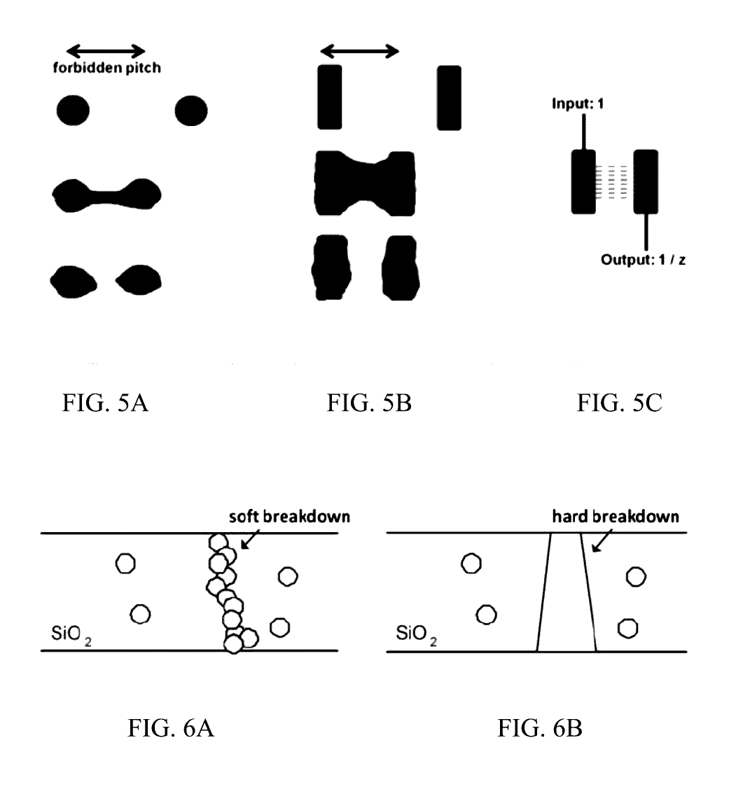

For instance, a top-down view in FIG. 5(a) illustrates how two adjacent vias placed at a forbidden pitch zone can either be shorted to each other or remain disconnected. As seen in a cross-section view presented in FIG. 5(b), the two vias can be merged or remain separated. Because of the different outcomes, a random hard-defect shorted path can be formed as demonstrated in FIG. 5(c), and is composed of the two vias along with their connection. With two vias merged, an output is “1”; if the vias are not merged, the output is in a high impedance state or “0”.

Plasma Induced Gate Oxide Breakdown

During silicon wafer fabrication, radio frequency (RF) plasma processes can be used for etching, photoresist stripping, or even ion implantation. In a plasma ambient, metal segments or polysilicon electrodes, which are antenna segments, can be electrically charged by ions or electrons and therefore produce an antenna voltage. For antenna segments connected to gates, a resulting electrical stress from the antenna segments can potentially damage an underlying gate oxide and generate a conducting path from the gate to a substrate. This phenomenon is referred to as plasma induced gate oxide breakdown, or the antenna effect.

Gate oxide breakdown can be categorized into two types: soft breakdown and hard breakdown, where both types introduce significant sudden increase of a leakage current. For soft breakdown, a conducting path from a gate to a substrate is formed by charged traps in a gate oxide. Once there is conduction, new traps begin to accumulate due to thermal damage, which in turn increases a conductance. The feedback cycle eventually leads to thermal runway and oxide is physically melted in the breakdown spot. This type of breakdown is referred to as a hard breakdown. FIG. 6 provides an illustration of the two types of breakdown. In some instances, a gate leakage current of an oxide with breakdown is about 100 times to about 100,000 times larger than a leakage current of an oxide without breakdown.

To avoid the antenna effect, design rules of an antenna ratio (AR) (with AR=exposed antenna area/gate oxide area) are typically strictly followed during fabrication. Practical design rules of AR can range from about 100 to about 1000. However, while actions to mitigate against the antenna effect are typically performed during manufacturing, the antenna effect can be exploited as another randomness source of a LEDPUF.

During RF plasma process, charging of an antenna segment occurs when currents produced from ions and electrons do not cancel each other through each RF cycle. Though a maximum voltage rise over half of an RF period can be modeled, the actual voltage still cannot be practically predicted because the amounts of ions and electrons collected by the antenna segment are unpredictable. The higher a gate voltage is, the higher the probability for a gate oxide breakdown to occur, thus causing what is considered a device failure in typical manufacturing. A device is considered a failure if a gate leakage current is larger than a threshold. For instance, a leakage current larger than about 1 nanoampere (nA) indicates a soft or hard oxide breakdown based on a leakage current distribution. Since both soft breakdown and hard breakdown can induce about 100 times or more leakage current than a pristine oxide, they can be both considered as breakdown in an LEDPUF. The failure probability F can be specified according to the equation: −In(1−F)=D(AR)ⁿ, where D and n are constants depending on the gate oxide thickness, the plasma process, and the antenna material.

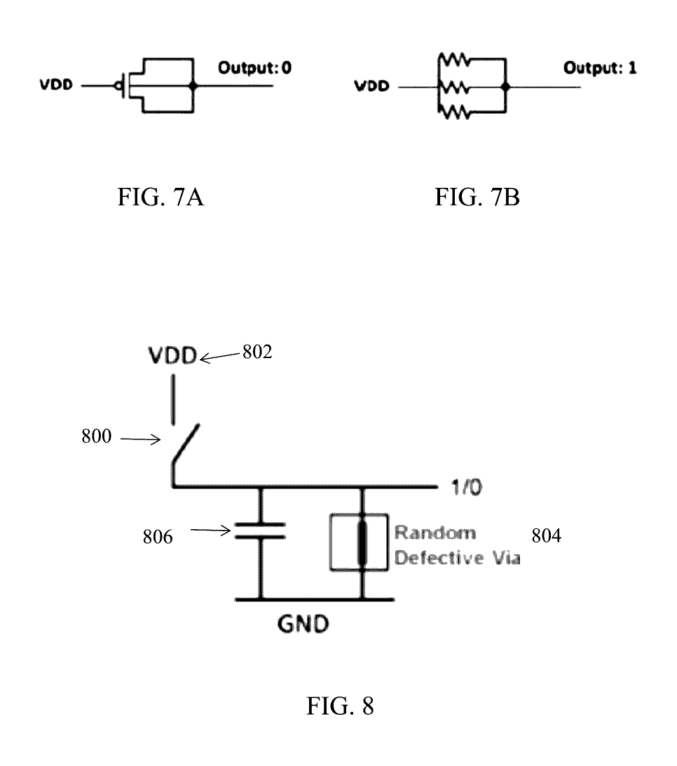

The gate oxide breakdown mechanism can be used to generate permanent and stable defects. FIG. 7 provides an illustration of a transistor that is designed to violate antenna rules, and its drain, source, and bulk terminals are connected to capture the effect of the gate oxide breakdown at various possible locations. If no breakdown occurs as depicted in FIG. 7A, the device is essentially a capacitor with substantially no current flowing to an output, and thus a digital “0” is generated; if a breakdown does occur, as depicted in FIG. 7B, the device becomes a set of resistors, and a current flow can be observed at the output, thus generating a digital “1”.

Having described some embodiments of random hard-defect shorted paths according to the present disclosure, circuits using the random defects are next discussed.

Random Signal Generation Circuit

In some embodiments, random hard-defect shorted paths are used to generate random signals as outputs. Random shorted path formations can be considered as random switches with permanent states that determine a distinct and stable logic function of a circuit. To avoid floating nets, an example of a random signal generation circuit is implemented as shown in FIG. 8. During function evaluation, a switch 800 connected to a power supply 802 is closed for a short period of time and then opened. A control signal to direct closing and opening of the switch 800 can be applied as an evaluation signal (EVA) for the random signal generation circuit. If a shorted path exists through a random defective via 804, an output will be low because a capacitor 806 is discharged through the shorted path. On the other hand, if the shorted path does not exist, the output will remain high.

Thus, in some embodiments, a random signal generation circuit includes a switch, where a first side of the switch is connected to a power source, and a second side of the switch is connected at a first node to an electrically parallel configuration of a capacitor and a random hard-defect shorted path. The parallel configuration of the capacitor and the random hard-defect shorted path are connected to a ground potential at a second node. When the switch is closed and then opened through application of an evaluation signal, a logic level at the first node is specified by the random hard-defect shorted path. This implementation translates shorted path formation randomness to random logic signals and mitigates against a floating net issue. Any leakage during evaluation can be further reduced by adding another control switch between the capacitor and the random hard-defect shorted path.

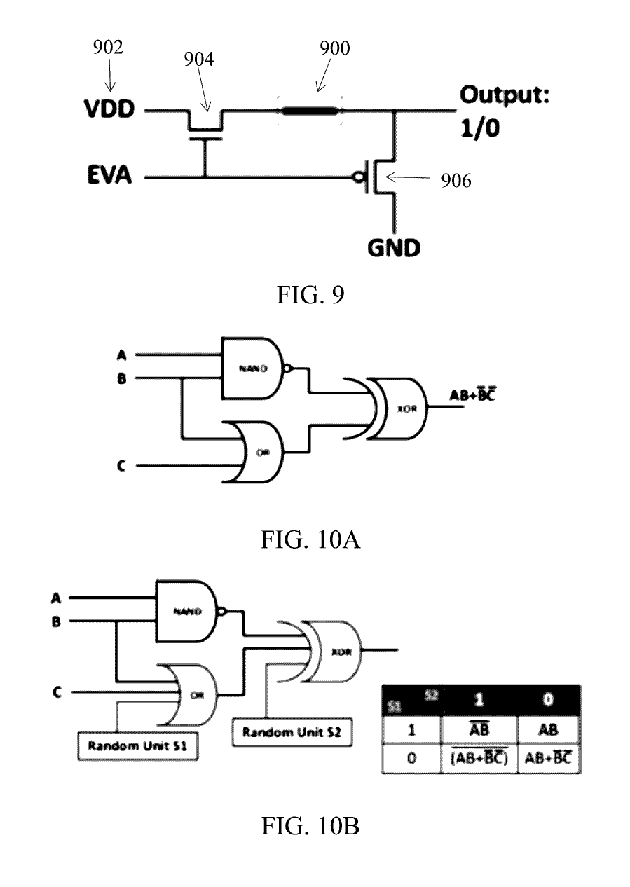

FIG. 9 is a schematic illustration of another example of a random signal generation circuit. Two sides of a random connection 900 are connected to a power source 902 and a ground potential through switches, here implemented as a pair of transistors 904 and 906. In the depicted example, the transistor 904 is a n-type metal-oxide-semiconductor field-effect transistor (MOSFET), and the transistor 906 is a p-type MOSFET). In a standby mode or before evaluation, an evaluation signal (EVA) is low, and an output of the circuit is “0”. During evaluation, EVA becomes high and is applied to gates of the transistors 904 and 906, and the output is either “1” or “0” depending on the permanent state of the random connection 900. If the random connection 900 is closed, the output is “1”; otherwise, the output is “0”.

Thus, in some embodiments, a random signal generation circuit includes a first switch, where a first side of the first switch is connected at a first node to an electrically in series configuration of a second switch and a random hard-defect shorted path, and a second side of the first switch is connected to a ground potential. The electrically in series configuration of the second switch and the random hard-defect shorted path are electrically connected to a power source at a second node. When the switches are closed through application of an evaluation signal, a logic level at the first node is specified by the random hard-defect shorted path.

Having described some embodiments of random signal generation circuits according to the present disclosure, implementations of PUFs using the random signal generation circuits are next discussed.

LEDPUF

In some embodiments, random hard-defect shorted paths are used to implement an LEDPUF by connecting the random hard-defect shorted paths, or random signal generation circuits including the hard-defect shorted paths, to inputs of a subset of logic gates within a logic circuit. As illustrated in FIG. 10A, a logic function of the circuit is AB+B⁻C⁻, and is implemented through connections between an NAND gate, an OR gate, and an XOR gate. In FIG. 10B, a random signal generation circuit S1 is included to apply an input to the OR gate, and a random signal generation circuit S2 is included to apply an input to the XOR gate. A number of possible output realizations of the logic circuit becomes four, as shown in the truth table of FIG. 10B. The number of logic functions grows exponentially with the number of random signal generation circuits inserted into the circuit; therefore, the probability of two LEDPUFs with a same logic function is negligible even with a few hundred of such random signal generation circuits.

Thus, in some embodiments, an LEDPUF can be operated by activating multiple switches to apply a voltage to respective sub-circuits connected to the switches. Each sub-circuit is connected to its respective switch at a node. Each sub-circuit includes an electrically parallel configuration of a capacitor and a random hard-defect shorted path (or other random hard-defect feature) such that, when the voltage is applied to the node, the capacitor charges. The switches are then deactivated to remove the voltage applied through the switches, such that the voltage at each node is set by a structure of the respective random defect as either a logic “1” or a logic “0”. A logic value at an output of a logic circuit is then measured. The logic circuit includes logic gates each having one or more inputs. The nodes of the sub-circuits are electrically connected to respective inputs of the logic gates. Accordingly, by switching and then removing power to the nodes of the sub-circuits, the logic circuit is configured to provide an output determined by the random defects.

In some embodiments, it can be desirable to incorporate diversity in random logic function realizations, such that the FHD inter-distance between any two PUFs is close to about 0.5. This may compete with rendering the PUFs immune to model building attacks—if it is easier to discover a test that distinguishes between two realizations, then model building attacks also can become easier. Logic circuit implementations can provide a solution, such as by making circuits sequential.

In any event, attacks on LEDPUFs are far more difficult than attacks on other PUFs, because the sheer number of possible realizations can be made very large with little silicon area. For instance, a number of available logic configurations is exponentially related to a number of inputs to a logic circuit. Additionally, sequential functional PUFs can be used, where a challenge can be a multi-cycle input pattern.

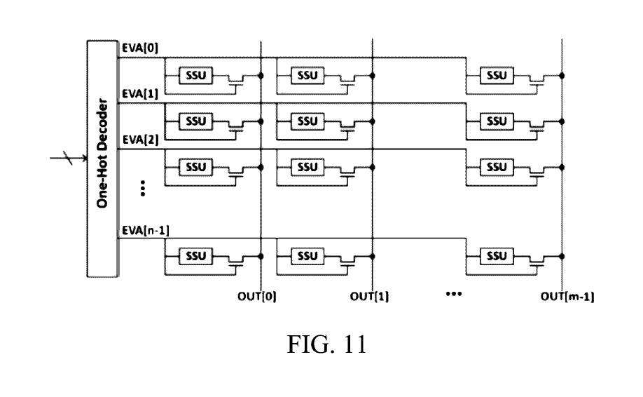

FIG. 11 is a schematic illustration of another example of an LEDPUF. The LEDPUF is implemented by arranging multiple random signal generation circuits SSUs in the form of an array. As depicted in FIG. 11, the LEDPUF includes the random signal generation circuits SSUs arranged in n rows and m columns, where a number of the random signal generation circuits SSUs is nm, and a number of CRPs is n. One of the rows is evaluated at a time, the LEDPUF includes a single decoder (labeled as “one-hot decoder”) connected to the array so that one bit of an evaluation signal EVA vector is logic “1”. A challenge applied into the decoder is a log(n)-bit input, and a response is a m-bit output.

Thus has been described herein techniques for using random hard-defect shorted paths in LEDPUFs, for improved security and stability of the LEDPUFs. Random hard-defect shorted paths were described by way of example, and it should be understood that random hard-defect shorted paths are a subset of a more general category of random hard-defect features. Other random hard-defect features include random fixed connectivity defects such as random hard-defect partial shorted paths or random hard-defect open paths. Accordingly, in aspects and embodiments encompassed by the present disclosure, in addition to or alternative to the use of random hard-defect shorted paths, random hard-defect partial shorted paths or random hard-defect open paths can be used to at least partially implement a logic function.

As used herein, the singular terms “a,” “an,” and “the” include plural referents unless the context clearly dictates otherwise. Thus, for example, reference to an object can include multiple objects unless the context clearly dictates otherwise.

As used herein, the terms “substantially,” “substantial,” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

As used herein, the terms “connect,” “connected,” and “connection” refer to an operational coupling or linking. Connected objects can be directly coupled to one another or can be indirectly coupled to one another, such as via another set of objects.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified. For example, a range of about 1 to about 200 should be understood to include the explicitly recited limits of about 1 and about 200, but also to include individual ratios such as about 2, about 3, and about 4, and sub-ranges such as about 10 to about 50, about 20 to about 100, and so forth.

While the disclosure has been described with reference to the specific embodiments thereof, it should be understood by those skilled in the art that various changes may be made and equivalents may be substituted without departing from the true spirit and scope of the disclosure as defined by the appended claims. In addition, many modifications may be made to adapt a particular situation, material, composition of matter, method, operation or operations, to the objective, spirit and scope of the disclosure. All such modifications are intended to be within the scope of the claims appended hereto. In particular, while certain methods may have been described with reference to particular operations performed in a particular order, it will be understood that these operations may be combined, sub-divided, or re-ordered to form an equivalent method without departing from the teachings of the disclosure. Accordingly, unless specifically indicated herein, the order and grouping of the operations is not a limitation of the disclosure.

What is claimed is:

1. A physical unclonable function, comprising:
a plurality of logic gates; and
a plurality of random signal generation circuits connected to the logic gates;
wherein, in at least a subset of the logic gates, each logic gate includes an input having a logic value that is specified by at least one of the random signal generation circuits.

2. The physical unclonable function of claim 1, wherein each of the random signal generation circuits includes a random hard-defect feature.

3. The physical unclonable function of claim 2, wherein each random hard-defect feature has a fixed connectivity state that specifies one of a plurality of distinct logic values.

4. The physical unclonable function of claim 2, wherein at least one random hard-defect feature includes a transistor including a carbon nanotube with metallic chirality.

5. The physical unclonable function of claim 2, wherein at least one random hard-defect feature includes a memristor in a low resistance state.

6. The physical unclonable function of claim 2, wherein at least one random hard-defect feature includes multiple merged vias.

7. The physical unclonable function of claim 2, wherein at least one random hard-defect feature includes a transistor including a gate oxide having a conducting path through the gate oxide.

8. The physical unclonable function of claim 1, wherein at least one of the random signal generation circuits includes a capacitor and a random hard-defect feature connected in parallel with the capacitor.

9. The physical unclonable function of claim 1, wherein at least one of the random signal generation circuits includes a switch and a random hard-defect feature connected in series with the switch.

10. A random signal generation circuit, comprising:
a switch, wherein a first side of the switch is configured for connection to a power source; and
an electrically parallel configuration of a capacitor and a random hard-defect feature, wherein the capacitor and the random hard-defect feature are connected to a second side of the switch at a first node, and are configured for connection to a ground potential at a second node,
wherein, when the switch is closed and then opened, a logic value at the first node is specified by the random hard-defect feature.

11. A method of evaluating a physical unclonable function, comprising:
activating a plurality of switches to apply a voltage to respective sub-circuits connected to the switches, wherein each of the sub-circuits includes a respective random hard-defect feature; and
deriving logic values from outputs of the sub-circuits, wherein an output of each of the sub-circuits is specified by a fixed connectivity state of the respective random hard-defect feature, and is derived as either a logic one or a logic zero.

12. The method of claim 11, further comprising:
applying the outputs of the sub-circuits to a logic circuit including a plurality of logic gates; and
deriving a logic value from an output of the logic circuit.
